(19) United States
(12) Patent Application Publication
(10) Pub. No.: US 2015/0222291 A1
(43) Pub. Date: Aug. 6, 2015

(54) MEMORY CONTROLLER, STORAGE DEVICE AND MEMORY CONTROL METHOD

(71) Applicant: Kabushiki Kaisha Toshiba, Minato-ku (JP)

(72) Inventors: Naoaki KOKUBUN, Yokohama (JP); Kohsuke HARADA, Yokohama (JP)

(73) Assignee: Kabushiki Kaisha Toshiba, Minato-ku (JP)

(21) Appl. No.: 14/453,903

(22) Filed: Aug. 7, 2014

Related U.S. Application Data
(60) Provisional application No. 61/936,038, filed on Feb. 5, 2014.

(51) Int. Cl. H03M 13/11; G11C 29/04; G06F 11/10

(52) U.S. Cl. CPC H03M 13/1142; G06F 11/1068; G06F 11/1028; G11C 29/04

(57) ABSTRACT

According to one embodiment, a memory controller comprises an encoding unit that encodes first unit data and second unit data to generate a first codeword and a second codeword; a rearranging unit that extracts a first bit string in specific bit positions from each of the first and second codewords to generate first page data and to generate second page data containing the remaining bit strings other than the first bit strings respectively in the first and second codewords; and a write control unit that writes the first page data and the second page data respectively into a first page and a second page of a nonvolatile memory.

### CROSS-REFERENCE TO RELATED APPLICATIONS

This application is based upon and claims the benefit of priority from U.S. Provisional Application No. 61/936,038, filed on Feb. 5, 2014; the entire contents of which are incorporated herein by reference.

### FIELD

Embodiments described herein relate generally to a memory controller, a storage device and a memory control method.

### BACKGROUND

In a NAND flash memory (hereinafter called a NAND memory), page data to be written is error correction coded for protection. As a scheme of error correction coding, there is a method using LDPC (Low Density Parity Check) codes. In a region where the error rate is low, the probability of failing in decoding an LDPC code is affected by a set of bits linked in a specific relation (a trapping set).

### BRIEF DESCRIPTION OF THE DRAWINGS

FIG. 1 is a block diagram showing an example configuration of the storage device (semiconductor storage device) according to a first embodiment;

FIG. 2 is a schematic diagram showing the relation between the raw bit error rate and the frame error rate of LDPC codes;

FIG. 3 is a flow chart showing an example of the method of creating a table storing trapping sets;

FIG. 4 is a diagram showing an example of the method of storing trapping sets in a nonvolatile memory of the first embodiment;

FIG. 5 is a diagram showing an example of the procedure of writing into the nonvolatile memory of the first embodiment;

FIG. 6 is a diagram showing an example of the procedure of reading from the nonvolatile memory of the first embodiment;

FIG. 7 is a diagram showing an example of the method of storing trapping sets according to a second embodiment;

FIG. 8 is a diagram showing an example of the procedure of writing into a nonvolatile memory of the second embodiment; and

FIG. 9 is a diagram showing an example of the procedure of reading from the nonvolatile memory of the second embodiment.

### DETAILED DESCRIPTION

In general, according to one embodiment, a memory controller comprises an encoding unit that encodes first unit data and second unit data to generate a first codeword and a second codeword; a rearranging unit that extracts a bit string (first bit string) in specific bit positions from each of the first codeword and the second codeword to generate first page data and to generate second and subsequent page data containing the remaining bit strings (second bit strings) other than the first bit strings respectively in the first codeword and the second codeword; and a write control unit that writes the first page data and the second page data respectively into a first page and a second page of a nonvolatile memory.

Exemplary embodiments of a memory controller, a storage device and a memory control method will be explained below in detail with reference to the accompanying drawings. The present invention is not limited to the following embodiments.

### First Embodiment

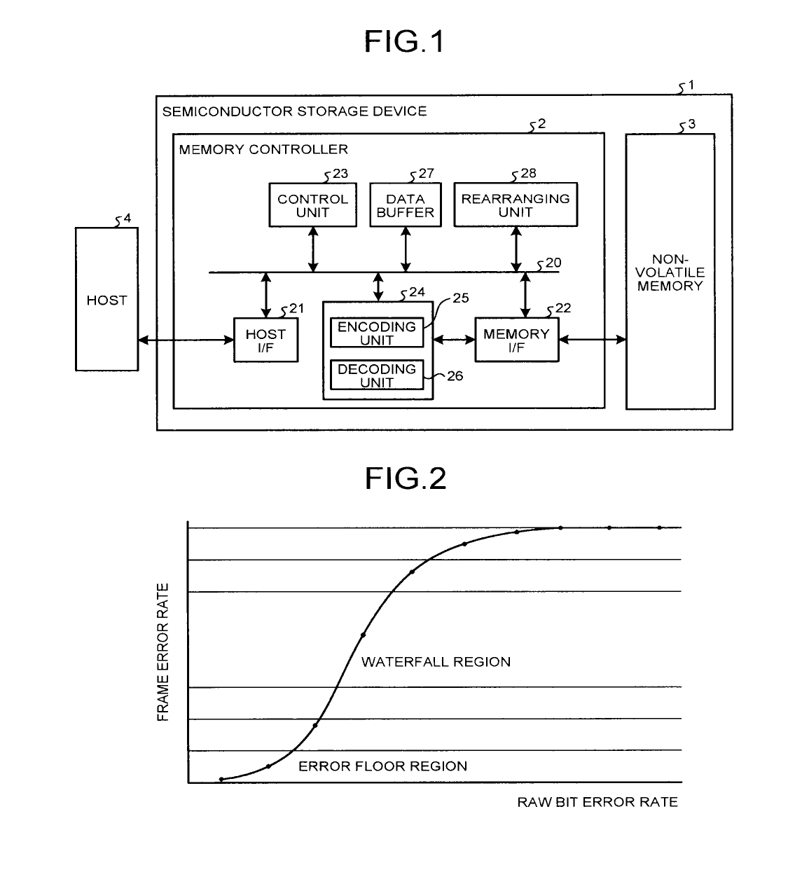

FIG. 1 is a block diagram of a configuration example of a storage device (a semiconductor storage device) according to a first embodiment. The semiconductor storage device 1 according to the present embodiment comprises a memory controller 2 and a nonvolatile memory 3. The semiconductor storage device 1 is connectable to a host 4. In FIG. 1, a state in which the semiconductor storage device 1 is connected to the host 4 is shown. The host 4 is, for example, an electronic device such as a personal computer or a mobile terminal.

The nonvolatile memory 3 is a nonvolatile memory configured to store data in a nonvolatile manner. The nonvolatile memory 3 is, for example, a NAND memory. Note that, in an example explained below, the NAND memory is used as the nonvolatile memory 3. However, the nonvolatile memory 3 can be a memory other than the NAND memory. In the NAND memory, in general, data is written and read out for each of write unit data called page.

The memory controller 2 controls writing into the nonvolatile memory 3 according to a write command received from the host 4. The memory controller 2 controls reading from the nonvolatile memory 3 according to a read command received from the host 4. The memory controller 2 comprises a host I/F 21, a memory I/F 22 (a write control unit), a control unit 23, an ECC (Error Correcting Code) unit 24, a data buffer 27, and a rearranging unit 28, which are connected to each other via an internal bus 20.

The host I/F 21 outputs commands, user data (write data), and the like received from the host 4 onto the internal bus 20. The host I/F 21 transmits user data read from the nonvolatile memory 3, responses from the control unit 23, and the like to the host 4.

The memory I/F 22 controls writing user data and the like into the nonvolatile memory 3 and reading from the nonvolatile memory 3 based on instructions from the control unit 23.

The control unit 23 collectively controls the semiconductor storage device 1. The control unit 23 is, for example, a CPU (Central Processing Unit), MPU (Micro Processing Unit), or the like. When receiving a command from the host 4 via the host I/F 21, the control unit 23 performs control according to the command. For example, the control unit 23, according to a command from the host 4, instructs the memory I/F 22 to write user data and parity into the nonvolatile memory 3. Also, the control unit 23, according to a command from the host 4, instructs the memory I/F 22 to read user data and parity from the nonvolatile memory 3.

The control unit 23 determines a storage area (memory area) on the nonvolatile memory 3 for user data stored in the data buffer 27. User data is stored in the data buffer 27 via the internal bus 20. The control unit 23 performs the determination of the memory area for data in a page unit (page data), which is a write unit. In the present description, unit data is defined as user data stored in one page of the nonvolatile memory 3. In the present embodiment, a codeword is generated by encoding, described later, for the unit data and stored as one page of data in one page of the nonvolatile memory 3. In the present description, the memory cells connected in common to one word line are referred to as a memory cell group. Where the memory cell is a single-level cell, the memory cell group corresponds to one page. Where the memory cell is a multi-level cell, the memory cell group corresponds to multiple pages. For example, when 2-bit storable multilevel cells are used, the memory cell group corresponds to two pages. The control unit 23 determines the memory area of the nonvolatile memory 3 for each unit data to be written into. Physical address is assigned to the memory area of the nonvolatile memory 3. The control unit 23 manages the write destination memory area of the unit data using the physical address. The control unit 23 instructs the memory I/F 22 to write user data into the nonvolatile memory 3 with specifying the determined memory area (physical address). The control unit 23 manages the correspondence between logical addresses of user data (logical addresses managed by the host 4) and physical addresses. When receiving a read command including a logical address from the host 4, the control unit 23 identifies the physical address corresponding to the logical address and instructs the memory I/F 22 to read user data with specifying the physical address.

The ECC unit 24 encodes unit data stored in the data buffer 27 to generate a codeword. The ECC unit 24 comprises an encoding unit 25 and a decoding unit 26. The encoding unit 25 encodes unit data written in the same page to generate a codeword. Here, an example where the encoding unit 25 performs LDPC encoding will be described. The encoding performed by the encoding unit 25 is not limited to this. As long as a restriction is imposed on the storage destination for a specific bit set out of the generated codeword, the operation of the present embodiment can be applied regardless of the encoding scheme. The decoding unit 26 decodes codeword with noise attributed to writing, reading, and storing, which is read from the nonvolatile memory 3.

The data buffer 27 temporarily stores user data received from the host 4 until it is stored in the nonvolatile memory 3 and temporarily stores data read from the nonvolatile memory 3 until it is transmitted to the host 4. The data buffer 27 is constituted by, e.g., a general-purpose memory such as an SRAM (Static Random Access Memory) or a DRAM (Dynamic Random Access Memory).

The rearranging unit 28 rearranges codewords generated by the encoding unit 25 with use of a table held therein. This table is a table having stored therein rules in rearranging generated codewords and is created in advance. The details of the table will be described later. The rearranging unit 28 rearranges data read from the nonvolatile memory 3 using the table.

FIG. 1 shows the example configuration where the memory controller 2 comprises the ECC unit 24 and the memory I/F 22, but the ECC unit 24 may be incorporated in the memory I/F 22. Further, the rearranging unit 28 may be incorporated in the ECC unit 24 or in the memory I/F 22.

Here, it is supposed that codewords generated by the encoding unit 25 are stored in the data buffer 27. Then, the rearranging unit 28 rearranges a codeword on the data buffer 27 using the table and stores the rearranged codeword in the data buffer 27. The memory I/F 22 writes the rearranged codeword on the data buffer 27 into the nonvolatile memory 3 based on an instruction from the control unit 23. When reading from the nonvolatile memory 3, the memory I/F 22 stores a codeword read from the nonvolatile memory 3 in the data buffer 27. The rearranging unit 28 rearranges the codeword on the data buffer 27 and stores the rearranged codeword in the data buffer 27.

Although the example where the data buffer 27 is used as a working memory for rearrangement has been described, a buffer other than the data buffer 27 may be used as a working memory for rearrangement. For example, since the ECC unit 24 generally has a buffer used for encoding and decoding, this buffer may be used as a working memory for rearrangement. Or without using a working memory for rearrangement, the rearranging unit 28 may perform rearrangement when transferring a codeword from the data buffer 27 to the memory I/F 22. Likewise, as to rearrangement when reading, the data buffer 27 or a buffer other than the data buffer 27 may be used as a working buffer. Or a working buffer does not have to be used.

The decoding failure probability of LDPC codes will be described. FIG. 2 is a schematic diagram showing the relation between the raw bit error rate and the frame error rate of LDPC codes. As shown in FIG. 2, in the relation between the raw bit error rate and the frame error rate, there are a waterfall region where the decoding failure probability changes sharply as the raw bit error rate changes and an error floor region where the phenomenon occurs that improvement in the decoding failure probability becomes less as the raw bit error rate changes. The error floor is affected by a set of bits linked in a specific relation (a trapping set). It is desirable that the error floor does not occur. Or, if it occurs, it is desirable that the decoding failure probabilities at which the error floor occurs are lower. Accordingly, encoding schemes are designed so as to remove trapping sets.

However, as the code rate increases (redundancy decreases), that is, as relational expressions between bits (bit constraints) become fewer, the degrees of freedom in changing the relational expressions become fewer, and hence it becomes difficult to remove all the trapping sets greatly affecting the error floor worsening. Thus, a trapping set may remain.

In the present embodiment, when storing a codeword in the nonvolatile memory 3, the trapping set is stored in a storage area having a low error occurrence probability. Thus, the error floor can be improved. For example, where memory cells storing four values per cell (memory cells of two bits per cell) are used, two bits stored in each memory cell correspond to two pages called a lower page, an upper page. The lower page and the upper page are generally different in error occurrence probability. Accordingly, the trapping set is stored in a page having a low error occurrence probability from among the lower page and the upper page. Or, if the error occurrence probability differs for each chip, the trapping set is stored in a chip having a low error occurrence probability. Or, if the error occurrence probability differs for each storage area such as storage area on a block basis, the trapping set may be stored in a storage area having a low error occurrence probability.

Although there is no restriction on the method of calculating the error occurrence probability on a storage area basis, for example, in the case of the lower page and the upper page, the error occurrence probability can be determined by the method of assigning voltage thresholds. Or, if on a chip basis or on a block basis, the numbers of write times, error occurrence frequencies, or the like may be recorded, and the error occurrence probability may be determined based on the past numbers of write times, error occurrence frequencies, or the like.

The trapping set is calculated by simulation or the like beforehand at the time of code designing. There is no restriction on the method of simulation. For example, a decoding simulation with data having a codeword randomly given errors as an input is performed, and which bits are in error is recorded and analyzed at decoding failure. By this means, trapping sets having a bad effect are obtained. The trapping sets obtained in this way are stored in the form of a table.

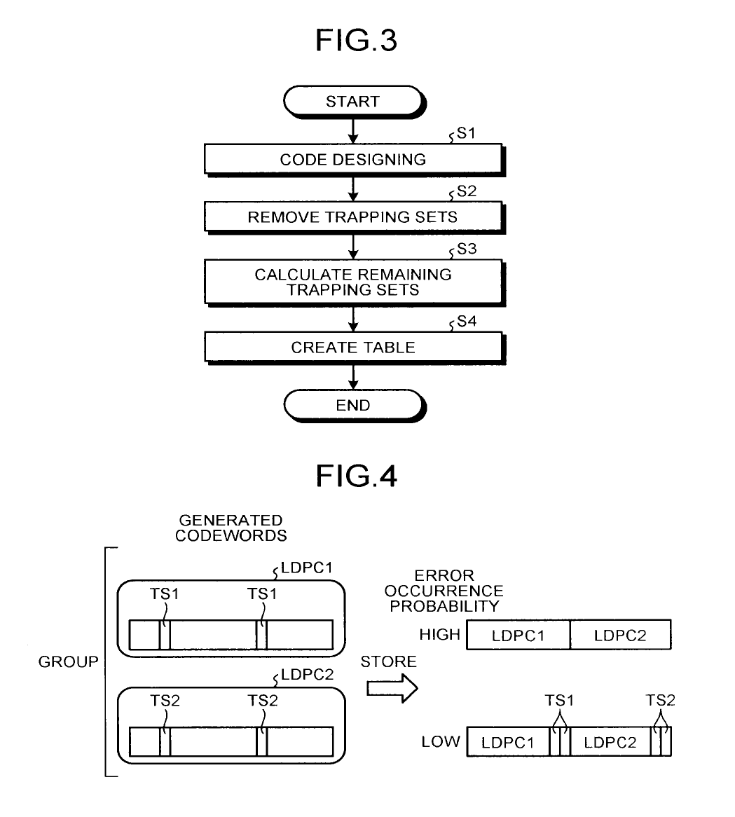

FIG. 3 is a flow chart showing an example of the method of creating a table storing trapping sets. As shown in FIG. 3, first, code designing is performed (step S1). Then, the removal of trapping sets is performed (step S2). Next, the remaining trapping sets are calculated by simulation or the like (step S3). A table is created based on the calculating result of step S3 (step S4).

There is no restriction on the format of the table storing trapping sets, and information by which bit positions in the codeword of the bits corresponding to a trapping set are identifiable is stored. For example, let a codeword be formed of n bits and the bit positions in the codeword be denoted by numbers of from 0 to n−1. Then, numbers denoting the bit positions corresponding to a trapping set are stored in the table.

FIG. 4 is a diagram showing an example of the method of storing trapping sets in the nonvolatile memory 3 of the present embodiment. The left side of FIG. 4 shows codewords generated by the encoding unit 25. The right side shows a state where two page data produced by rearranging these codewords are stored in the nonvolatile memory 3. Here, two codewords form a group for rearrangement. FIG. 4 shows an example where two codewords LDPC1, LDPC2 form a group. It is supposed that the control unit 23 has determined two storage areas (two storage pages) on the nonvolatile memory 3 for these two codewords and that these two storage areas differ in error occurrence probability. Let TS1 be data of the bit positions corresponding to a trapping set in LDPC1 and TS2 be data of the bit positions corresponding to a trapping set in LDPC2.

In the present embodiment, the rearranging unit 28 realizes data of the bit positions corresponding to the trapping set in each of LDPC1 and LDPC2 (hereinafter called the bit string of a trapping set) based on the table and stores these data in a place having a low error occurrence probability in the nonvolatile memory 3. The other bits (second bit string) than the bit string (first bits) of the trapping set in each codeword (LDPC1, LDPC2 in FIG. 4) are distributed to and stored in a storage area (first page) having a low error occurrence probability and a storage area (second page) having a high error occurrence probability. For example, it is assumed that memory cells of two bits per cell are used and that one of the storage areas for LDPC1 and LDPC2 determined by the control unit 23 is the lower page with the other being the upper page. Of the lower page and the upper page, let the page having a higher error occurrence probability be a first page and the other be a second page. The rearranging unit 28 rearranges the bits of generated LDPC1 or LDPC2 such that the bit strings of trapping sets in LDPC1 and LDPC2 are to be stored in the second page. The rearranging unit 28 performs the rearrangement such that the bits other than the bit strings of the trapping sets are distributed to and stored in the first page and the second page. In order to make the amounts of data to be stored in the first and second pages the same, of the bits other than the bit strings of the trapping sets, more bits are stored in the first page than in the second page.

When reading from the nonvolatile memory 3, data of the two pages shown on the right side of FIG. 4 is read, and the rearranging unit 28, referring to the table, performs rearrangement to restore the two codewords shown on the left side of FIG. 4.

Note that FIG. 4 is illustrative and that the number of bits forming the trapping set and the bit positions in which the bit string of the trapping set is stored are not limited to the example of FIG. 4. For example, such rearrangement may be performed that a storage page is assigned on a per bit basis as follows. It is assumed that the page data in the upper part of the right side of FIG. 4 is stored in the first page and that the page data in the lower part is stored in the second page. In this case, for example, the rearranging unit 28, for LDPC1 (the upper part of the right side of FIG. 4) generated by the encoding unit 25, assigns bits alternately to two pages on a per bit basis, for example, even-numbered bits to the first page and odd-numbered bits to the second page. And as to the bits in the bit positions of the trapping set stored in the table, even even-numbered hits are assigned to the second page. In this case, since two consecutive bits are assigned to the second page, the next odd-numbered bit is assigned to the first page. Likewise, for LDPC2, assigns bits to the first and second pages on a per bit basis, so that the bit strings of the trapping sets can be gathered in the second page. Although the description has been made that rearrangement is performed referring to the table, rearrangement may be performed in a fixed order without referring to the table each time because the bit positions of the bit string of the trapping set are fixed. Also, when reading from the nonvolatile memory 3, likewise, rearrangement may be performed in a fixed order without referring to the table each time.

Although FIG. 4 shows an example where a group is formed of two codewords (two pages worth of codewords), a group may be formed of three or more codewords. For example, where cells of three bits per cell are used, the bit strings of the trapping sets of the codewords in the group can be stored in the page having the smallest error occurrence probability of three pages corresponding to three bits stored in one memory cell. The bits other than the bit strings of the trapping sets are distributed to the three pages.

Where the codewords in the group are distributed to and stored in chips different in error occurrence probability, the bits of the trapping sets of the codewords in the group are stored in a chip having a low error occurrence probability. The bits other than the bit strings of the trapping sets are distributed to and stored in the chip having a low error occurrence probability and the other chips. When reading, reading from multiple pages forming one group is performed. Accordingly, if reading from chips in parallel can be performed, data of one group is distributed to and stored in the different chips, and by reading from the chips simultaneously, the read time can be shortened.

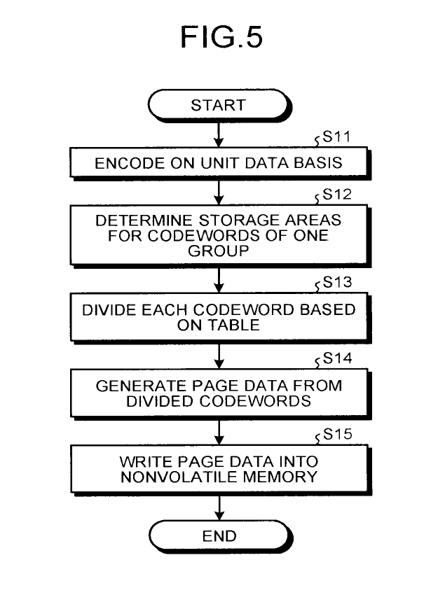

FIG. 5 is a diagram showing an example of the procedure of writing into the nonvolatile memory 3 of the present embodiment. The encoding unit 25 encodes on a unit data basis to generate codewords (step S11). The control unit 23 determines the storage areas on the nonvolatile memory 3 for the codewords of one group (step S12). Here, the control unit 23 determines a storage page on the nonvolatile memory 3 for each codeword on the data buffer 27 before rearrangement by the rearranging unit 28. Further, it is supposed that the control unit 23 realizes the error occurrence probability for each type of page (upper, lower, etc.) on the nonvolatile memory 3, for each chip, or so on. Then, the control unit 23 determines, for each group, the storage page for each codeword such that the error occurrence probabilities of the multiple storage pages forming the group are two or more different ones. For example, as in the example of FIG. 4, the storage areas for the two codewords forming a group are determined to be a page having a high error occurrence probability and a page having a low error occurrence probability. Not being limited to this, the control unit 23 may determine storage pages on the nonvolatile memory 3 after rearrangement by the rearranging unit 28. In this case, for example, the control unit 23 assigns storage areas of the nonvolatile memory 3 on a group basis (i.e., multiple storage pages to a group), and the rearranging unit 28 may determine the storage page for each page data in the group. In this case, the rearranging unit 28 determines the storage destination for page data including the bit string of a trapping set to be a storage page having a low error occurrence probability.

The rearranging unit 28 divides each codeword into parts on a storage-destination page basis based on the table (step S13). In the case of the example of FIG. 4, the rearranging unit 28 extracts the bit string of a trapping set to be stored in the first page from LDPC1 so as to be one divided data and separates the bits other than the bit string of the trapping set to be stored in the first page out of LDPC1 into bits to be stored in the first page and bits to be stored in the second page. LDPC2 is also divided likewise.

The rearranging unit 28 generates page data from divided codewords (step S14). The rearranging unit 28 writes the generated page data over the area where the original codeword (from which the page data was generated) has been stored on the data buffer 27. At this time, the rearranging unit 28 writes page data in which the bit strings of trapping sets are gathered (the lower part of the right side in the example of FIG. 4) over the area for a codeword to be stored in a page having a low error occurrence probability. The rearranging unit 28 has been notified by the control unit 23 of information about whether a page determined to be the storage area for each codeword is one having a low error occurrence probability.

The control unit 23 notifies the correspondence between the storage position of page data on the data buffer 27 and the storage area on the nonvolatile memory 3 to the memory I/F 22. The memory I/F 22 stores the page data on the data buffer 27 in the nonvolatile memory 3 based on the notification from the control unit 23 (step S15). Having undergone the above process, the page data in which the bit strings of trapping sets are gathered is stored in a page having a low error occurrence probability.

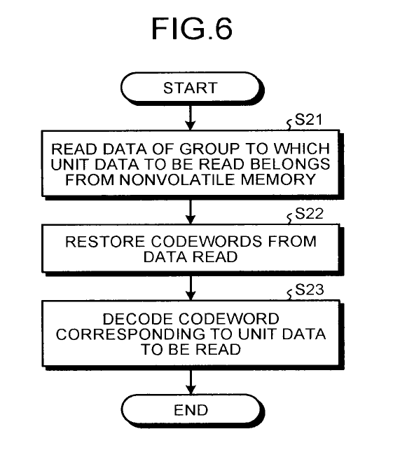

FIG. 6 is a diagram showing an example of the procedure of reading from the nonvolatile memory 3 of the present embodiment. The control unit 23 instructs the memory I/F 22 to read data of the group to which unit data to be read belongs from the nonvolatile memory 3, and the memory I/F 22 reads the data from the nonvolatile memory 3 based on the instruction (step S21). The data read from the nonvolatile memory 3 is stored in the data buffer 27.

The rearranging unit 28, referring to the table, restores codewords from the data read from the nonvolatile memory 3 (step S22). That is, rearrangement is performed such that the codewords rearranged when writing return to the state before that rearrangement (the codewords on the right side of FIG. 4).

The control unit 23 instructs the decoding unit 26 to decode the codeword corresponding to unit data to be read, and the decoding unit 26 decodes the codeword based on the instruction (step S23). Having undergone the above process, unit data (user data) after decoding is obtained.

Because the positions of bits forming the trapping set in a codeword are fixed regardless of information which is the input to the encoding, the rearranging unit 28 does not need to refer to the table each time when writing. The rearrangement may be realized by configuring the rearranging unit 28 to divide a codeword into data of pages to be distributed in a fixed order. The same applies to rearrangement when reading.

Although in the present embodiment one codeword is generated using user data (unit data) to be written into one page, one codeword may be generated using multiple unit data. Or unit data may be divided into multiple parts, and multiple codewords generated using divided data may be stored in one page. Also in these cases, with a group being formed of multiple pages different in error occurrence probability, codewords are rearranged such that the bit strings of trapping sets of the codewords in the group are stored in a page having a low error occurrence probability, and thereby the error floor can be improved.

In the above example, the bit strings of trapping sets in LPDC codes are gathered in a page having a low error occurrence probability. But, not being limited to this, with another encoding scheme, if specific bit sets in codewords affects the error occurrence probability, by gathering the specific bit sets in a page having a low error occurrence probability, the error rate after decoding can be reduced.

### Second Embodiment

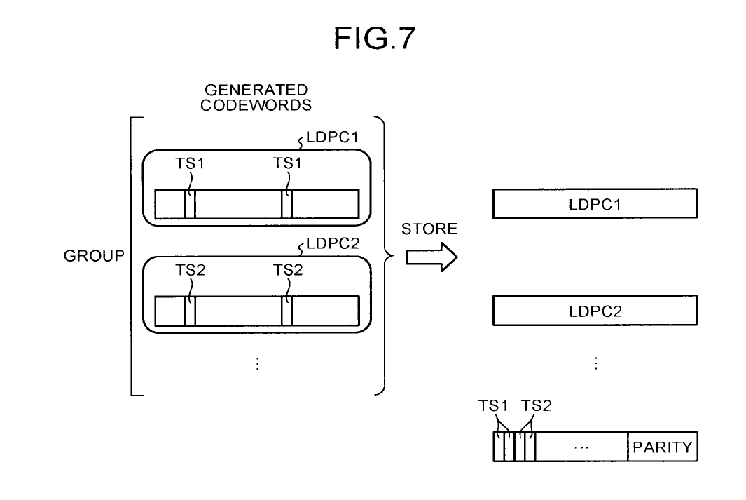

FIG. 7 is a diagram showing an example of the method of storing trapping sets in a semiconductor storage device 1 according to the second embodiment. The configuration of the semiconductor storage device 1 of the present embodiment is the same as in the first embodiment. Duplicate description of the same parts as in the first embodiment is omitted, and different parts than in the first embodiment will be described below.

Although in the first embodiment the example where there is lopsidedness in error occurrence probability between storage areas has been described, even where no lopsidedness exists, by gathering trapping sets in a page to add parity to and to store, the error floor can be improved.

In the present embodiment, as shown in FIG. 7, multiple codewords generated by the encoding unit 25 form a group. As shown on the left side of FIG. 7, the encoding unit 25 generates codewords LDPC1, LDPC2, . . . . The rearranging unit 28 extracts the bit strings of trapping sets from these codewords. The encoding unit 25 encodes the extracted bit strings of trapping sets to produce parity. There is no restriction on the encoding scheme used for this. The rearranging unit 28 generates page data to be formed of the bit strings of trapping sets and corresponding parity as shown in the lowest part of the right side of FIG. 7. The page data formed of the bit strings of trapping sets and corresponding parity is hereinafter called TS page data. Although FIG. 7 shows an example where the bit strings of trapping sets and parity are separated, an encoding scheme in which data and parity are not separated may be used. In this case, TS page data shown in the lowest part of FIG. 7 is a codeword into which the bit strings of trapping sets are encoded. Although herein the encoding unit 25 encodes the bit strings of trapping sets, the rearranging unit 28 may encode the bit strings of trapping sets, or another encoding unit than the encoding unit 25 and the rearranging unit 28 may be added to encode the bit strings of trapping sets.

The rearranging unit 28 generates page data containing the codeword except the bit string of a trapping set for each codeword generated by the encoding unit 25 (LDPC1, LDPC2, . . . on the right side of FIG. 7). At this time, page data containing the original codeword with the bit string of a trapping set remaining may be generated (the bit strings of trapping sets are also contained in LDPC1, LDPC2, on the right side of FIG. 7). Or the bit string of a trapping set may be removed from the original codeword to generate page data (the bit strings of trapping sets are not contained in LDPC1, LDPC2, on the right side of FIG. 7). In the case where page data containing the original codeword with the bit string of a trapping set remaining is generated, there is the advantage that when succeeding in decoding a read codeword, TS page data does not need to be read. In the case where the bit string of a trapping set is removed from the original codeword to generate page data, there is the advantage that duplicate data (the bit string of a trapping set) does not need to be stored in the nonvolatile memory 3, although TS page data must be read.

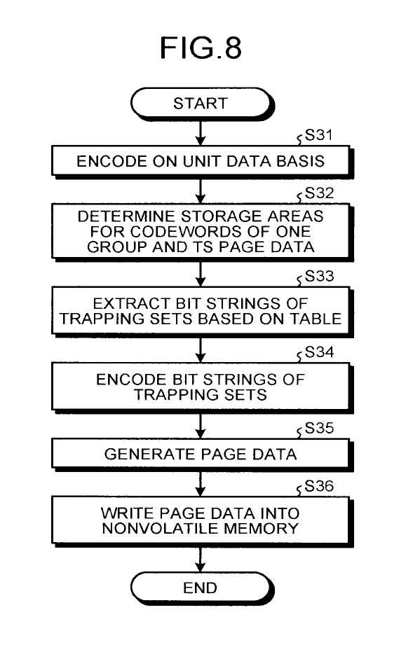

FIG. 8 is a diagram showing an example of the procedure of writing into the nonvolatile memory 3 of the present embodiment. In step S41, as in step S11 of the first embodiment, the encoding unit 25 encodes on a unit data basis to generate codewords (step S31). The control unit 23 determines the storage areas on the nonvolatile memory 3 for the codewords of one group and TS page data (step S32). The rearranging unit 28 extracts the bit strings of trapping sets from multiple codewords in the group (step S33). The encoding unit 25 encodes the extracted bit strings of trapping sets to produce parity (step S34).

The rearranging unit 28 generates page data containing the codeword except the bit string of a trapping set and TS page data for each codeword generated by the encoding unit 25 (step S35). The control unit 23 notifies the correspondence between the storage position of page data on the data buffer 27 and the storage area on the nonvolatile memory 3 to the memory I/F 22. The memory I/F 22 stores the page data on the data buffer 27 in the nonvolatile memory 3 based on the notification from the control unit 23 (step S36).

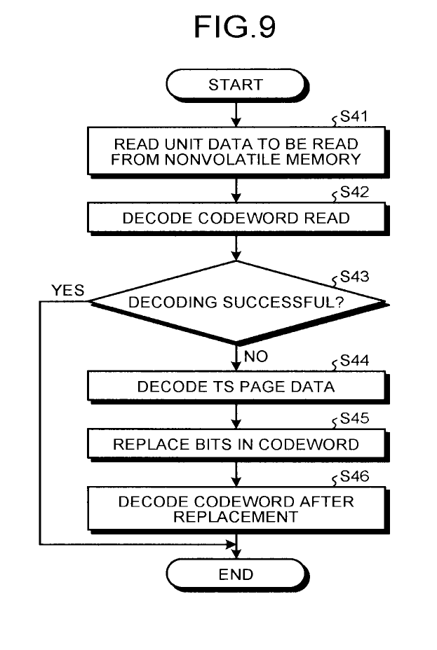

FIG. 9 is a diagram showing an example of the procedure of reading from the nonvolatile memory 3 of the present embodiment. With reference to FIG. 9, the procedure of reading will be described on the premise that page data containing the original codeword with the bit string of a trapping set remaining is generated. The control unit 23 instructs the memory I/F 22 to read the codeword corresponding to unit data to be read from the nonvolatile memory 3, and the memory I/F 22 reads the data from the nonvolatile memory 3 based on the instruction (step S41).

The decoding unit 26 decodes the codeword read from the nonvolatile memory 3 (step S42). The decoding unit 26 notifies whether it has succeeded in decoding to the control unit 23. The control unit 23 determines whether it has succeeded in decoding (step S43), and if having succeeded (Yes at step S43), finishes reading. If having failed in decoding (No at step S43), the control unit 23 reads TS page data to decode (step S44). Specifically, the control unit 23 instructs the memory I/F 22 to read TS page data corresponding to the codeword to be read. The memory I/F 22 reads the TS page data from the nonvolatile memory 3 based on the instruction from the control unit 23. Then, the decoding unit 26 decodes the TS page data. Thus, the bit strings of the trapping sets are decoded.

The rearranging unit 28 replaces data of the bit positions corresponding to the trapping set of the codeword read from the nonvolatile memory 3 with bit values of the decoded trapping set (step S45). The decoding unit 26 decodes the codeword after the bit value replacement (step S46).

In the case where the bit string of a trapping set is removed from the original codeword to generate page data, TS page data is also read from the nonvolatile memory 3 in step S41. Then, without executing steps S42, S43, S44, step S45 and later steps are executed.

As such, in the present embodiment, the bit strings of trapping sets are gathered to add parity to and to store in the nonvolatile memory 3. Thus, the probability that errors will remain in the bit strings of trapping sets can be reduced, so that the error floor can be improved.

Note that the first embodiment and the present embodiment may be combined. For example, although in the example of FIG. 7 the bits except the bit strings of trapping sets are stored without being distributed to multiple pages, they may be distributed to and stored in multiple pages as in the first embodiment. Further, where there is lopsidedness in error occurrence probability, TS page data in FIG. 7 may be stored in a page having a low error occurrence probability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller which controls a nonvolatile memory, comprising:
an encoding unit configured to encode first unit data to generate a first codeword and encodes second unit data to generate a second codeword;
a rearranging unit configured to:
extract a first bit string that is a bit string in specific bit positions from each of the first codeword and the second codeword;
generate first page data containing the extracted first bit strings; and
generate second page data containing second bit strings that are the remaining bit strings other than the first bit strings respectively in the first codeword and the second codeword; and
a write control unit configured to write the first page data into a first page of the nonvolatile memory and writes the second page data into a second page of the nonvolatile memory.

2. The memory controller according to claim 1, wherein the first page has a lower error occurrence probability than the second page.

3. The memory controller according to claim 1, wherein the rearranging unit generates the first page data and the second page data such that the second bit string of the first codeword is distributed to and included in the first page data and the second page data and that the second bit string of the second codeword is distributed to and included in the first page data and the second page data.

4. The memory controller according to claim 3, further comprising:
a decoding unit configured to decode the first and the second codeword with noise attributed to writing, reading, and storing,
wherein when reading the first codeword or the second codeword from the nonvolatile memory, the memory controller reads the first page data and the second page data from the nonvolatile memory, and the rearranging unit rearranges the first page data and the second page data read from the nonvolatile memory to restore the codeword, which is subject to reading, and inputs the restored codeword subject to reading into the decoding unit.

5. The memory controller according to claim 1, wherein the encoding unit encodes the first bit strings of the first codeword and the second codeword to produce parity, and the first page data is generated to be formed of all the first bit strings and the parity,
wherein the rearranging unit generates the second page data to be formed of the second bit string of the first codeword and generates third page data to be formed of the second bit string of the second codeword, and
wherein the write control unit writes the third page data into a third page of the nonvolatile memory.

6. The memory controller according to claim 5, further comprising:
a decoding unit configured to decode the second page data read from the nonvolatile memory,
wherein when having failed in decoding the second page data, the memory controller reads the first page data from the nonvolatile memory and decodes the read first page data and replaces bit values in the bit positions of the first bit string out of the second page data with corresponding bit values of the decoded first page data, and the decoding unit decodes the second page data after the replacement.

7. The memory controller according to claim 1, wherein the encoding unit generates the first codeword to an n'th codeword (n is an integer greater than or equal to three) and encodes the first bit strings of the first to n'th codewords to produce parity, and
wherein the rearranging unit generates (i+1)'th page data to be formed of the second bit string of the i'th codeword (i is greater than or equal to three and less than or equal to n),
wherein the write control unit writes the i'th page data into an i'th page of the nonvolatile memory, and
wherein the size of data to be stored in the first page coincides with the data size of the first bit strings of all the first to n'th codewords and the parity.

8. The memory controller according to claim 1, wherein the encoding is LDPC encoding.

9. The memory controller according to claim 8, wherein the first bit string is the bit string of a trapping set.

10. A storage device comprising:
a nonvolatile memory;
an encoding unit configured to encode first unit data to generate a first codeword and encodes second unit data to generate a second codeword;
a rearranging unit configured to:
extract a first bit string that is a bit string in specific bit positions from each of the first codeword and the second codeword;
generate first page data containing the extracted first bit strings; and
generate second page data containing second bit strings that are the remaining bit strings other than the first bit strings respectively in the first codeword and the second codeword; and
a write control unit configured to write the first page data into a first page of the nonvolatile memory and writes the second page data into a second page of the nonvolatile memory.

11. The storage device according to claim 10, wherein the first page has a lower error occurrence probability than the second page.

12. The storage device according to claim 10, wherein the rearranging unit generates the first page data and the second page data such that the second bit string of the first codeword is distributed to and included in the first page data and the second page data and that the second bit string of the second codeword is distributed to and included in the first page data and the second page data.

13. The storage device according to claim 12, further comprising:
a decoding unit configured to decode the first and the second codeword with noise attributed to writing, reading, and storing,
wherein when reading the first codeword or the second codeword from the nonvolatile memory, the memory controller reads the first page data and the second page data from the nonvolatile memory, and the rearranging unit rearranges the first page data and the second page data read from the nonvolatile memory to restore the codeword, which is subject to reading, and inputs the restored codeword subject to reading into the decoding unit.

14. The storage device according to claim 10, wherein the encoding unit encodes the first bit strings of the first codeword and the second codeword to produce parity and generates the first page data to be formed of all the first bit strings and the parity,
wherein the rearranging unit generates the second page data to be formed of the second bit string of the first codeword and generates third page data to be formed of the second bit string of the second codeword, and
wherein the write control unit writes the third page data into a third page of the nonvolatile memory.

15. The storage device according to claim 14, further comprising:
a decoding unit configured to decode the second page data read from the nonvolatile memory,
wherein when having failed in decoding the second page data, the memory controller reads the first page data from the nonvolatile memory and decodes the read first page data and replaces bit values in the bit positions of the first bit string out of the second page data with corresponding bit values of the decoded first page data, and the decoding unit decodes the second page data after the replacement.

16. The storage device according to claim 10, wherein the encoding unit generates the first codeword to an n'th codeword (n is an integer greater than or equal to three) and encodes the first bit strings of the first to n'th codewords to produce parity, and
wherein the rearranging unit generates (i+1)'th page data to be formed of the second bit string of the i'th codeword (i is greater than or equal to three and less than or equal to n),
wherein the write control unit writes the i'th page data into an i'th page of the nonvolatile memory, and
wherein the size of data to be stored in the first page coincides with the data size of the first bit strings of all the first to n'th codewords and the parity.

17. The storage device according to claim 10, wherein the encoding is LDPC encoding.

18. The storage device according to claim 17, wherein the first bit string is the bit string of a trapping set.

19. A memory control method which controls a nonvolatile memory, comprising:
encoding first unit data to generate a first codeword and encoding second unit data to generate a second codeword;
extracting a first bit string that is a bit string in specific bit positions from each of the first codeword and the second codeword;
generating first page data containing the extracted first bit strings;
generating second page data containing second bit strings that are the remaining bit strings other than the first bit strings respectively in the first codeword and the second codeword; and
writing the first page data into a first page of the nonvolatile memory and writing the second page data into a second page of the nonvolatile memory.
